(19) United States
(12) Patent Application Publication
(10) Pub. No.: US 2001/0009372 A1
(43) Pub. Date: Jul. 26, 2001

(54) Pipe testing apparatus and method

(76) Inventor: John T. Kuo, Blauvelt, NY (US)

Correspondence Address: ROBERT B. HUGHES, HUGHES & SCHACHT, P.S., 2801 MERIDIAN STREET, SUITE 1, BELLINGHAM, WA, 98225-2412, US

(21) Appl. No.: 09/796,402

(22) Filed: Feb. 28, 2001

Related U.S. Application Data
(63) Continuation of application No. 09/133,286, filed on Aug. 12, 1998, now abandoned.
(60) Provisional application No. 60/055,671, filed on Aug. 14, 1997.

(51) Int. Cl. G01R 27/04; G01R 27/32

(52) U.S. Cl. 324/644

(57) ABSTRACT

A system and method for detecting anomalies such as corrosion or other defects in or on conductive containers such as pipes, pipelines, separator containers, and storage tanks. An electromagnetic pulse is introduced onto the surface of the container itself, if not insulated or shielded, or the surface of the very outer layer of the shield or insulation, if the container is insulated and shielded, of the conductive container at a first test location such that a plurality of electromagnetic signals propagate from the first test location to a second test location. The electromagnetic signals are detected at the second location and analyzed for differences in electromagnetic characteristics that indicate the presence or absence of electromagnetic anomalies related to corrosion and/or defects. Each electromagnetic signal propagates along a unique path, and the corrosion is likely to lie on some but not all of these paths. The process as described is a forward detection process, and a reverse detection process may be employed to improve anomaly detection.

### RELATED APPLICATIONS

This application claims priority of U.S. Provisional Patent Application Ser. No. 60/055,671, which was filed on Aug. 14, 1997.

### BACKGROUND OF THE INVENTION

a) Field of the Invention

The present invention relates to a system, apparatus and method for testing large-diameter elongate objects such as pipes or pipelines and the like or cylindrical three-dimensional objects or vessels such as first stage separators, storage tanks and the like and is directed toward the problem of detecting corrosion, defects or other anomalies to the pipe under conditions where access and/or visual inspection of the pipe, storage tanks, or first stage separators is either impossible or impractical.

b) Background Art

In petroleum producing fields, containers such as large diameter pipe(s) or pipeline(s) and vessels such as storage tanksor separators are used to transport and/or store petroleum or petroleum products as liquids, gasses, or condensates for long distances and/or long periods of time. The diameters of these pipes or pipelines often reach 24, 36 to 60 inches or larger. The present patent application specifically addresses the detection of anomalies such as corrosion or other defects under insulation and shield for containers such as very large diameter pipe(s) or pipeline(s), storage tanks, and separators. As a matter of fact, the larger the diameter the better the resolution will be. These containers are invariably made of carbon steel, and are under intensive heat and high carrying pressure. The exterior of these containers are often insulated, with the insulating layers and shield being as great as approximately 1 to 5 inches in thickness, or outside of this range as shown in FIG. 1.

In the present application, the term “container” is used to refer both to elongate pipes or pipelines for containing fluids and to three dimensional vessels for containing fluids such as separators or storage tanks. The term “anomaly” is used herein to refer to corrosion, structural or metallurgical defects or variations, and other irregularities in the container under test. But because the present application is of particular interest in detecting corrosion, that application of the present invention will be described herein in detail. The present application makes clear, however, that the methodology used to detect corrosion may be applied to other container anomalies.

For safety and environmental considerations and avoiding costly shut-down, the integrity of these fluid containers must be maintained Corrosion in or on containers such as pipe(s) or pipeline(s), storage tanks, and/or separators could easily occur, mainly due to the invasion of moisture collected between the insulating and shield layers and the container. Visual inspection of the steel container under insulation and shield involves stripping, the process of which is expensive and time consuming, and economically infeasible to accomplish with reasonable frequency.

It is the object of the present invention to provide a means of inspecting large diameter containers such as pipe(s), pipeline(s)), storage tanks, separators or the like under insulation and shield efficiently with a relatively high degree of reliability.

### DESCRIPTION OF THE DRAWINGS

FIG. 1 is a cross sectional view of a pipe or pipeline which could advantageously be inspected by the present invention, such as one having a sixty inch diameter with six inch thick insulation and an outer metallic shield,

FIG. 2A is a cross sectional view similar to FIG. 1, showing one operating mode of the present invention where the transmitter (sender) and receiver are at the same location at the 12 o'clock location on the pipe;

FIG. 2B is a view similar to FIG. 3A, but showing the transmitter (sender) at the 12 o'clock location on the pipe, and the receiver at the 3 o'clock location on the pipe;

FIG. 2C is a representation of the wave forms received in the operating mode of FIG. 2S;

FIG. 2D is a representation of the wave form resulting from the operation where the apparatus is arranged as shown in FIG. 2B;

FIG. 3 is a side elevational view, showing the sender/receiver, at the 12 o'clock location, being moved continuously along the longitudinal axis of the pipe, with this being accomplished in a manner to continuously collect electromagnetic data;

FIG. 4 is a schematic view showing the overall system of the present invention;

FIG. 5 is a single page from a RAMAC/GPR operating manual, dated January, 1995, illustrating a ground penetrating radar system which may be usable in the present invention;

FIG. 6 is a somewhat schematic perspective view illustrating the testing of a first stage separator in which the source and receiver are not in coincidence; and

FIG. 7 is a somewhat schematic perspective view illustrating the testing of a storage tank in which the source and receiver are not in coincidence.

### SUMMARY OF THE INVENTION

The present invention takes advantage of the electromagnetic wave propagation around and around the circumference of the pipe or pipeline until the electromagnetic waves are completely attenuated. In the following description, the positions of the source and the receiver are referenced to the direction of the container (pipe) as an operator traveling along the left side of the longitudinal axis of the vessel, pipe, or pipeline. The position of 12 o'clock is on the top of the pipe or pipeline, that of 6 o'clock is on the very bottom of the pipe or pipeline, and 3 o'clock and 9 o'clock are to the right and to the left of the cross section of the pipe or pipeline, respectively.

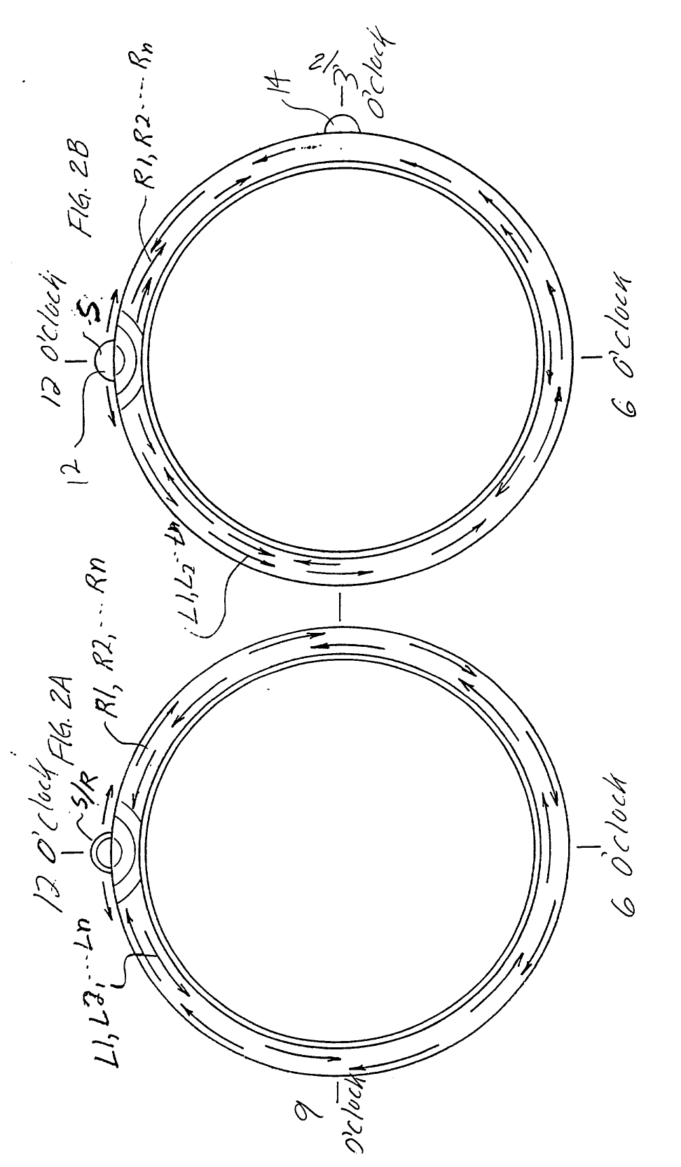

1) If the source (i.e. transmitter) designated by S and the receiver designated by R are in coincidence, as shown in FIG. 2A, with the transmitter and receiver being designated S/R, the electromagnetic wave emitted by the source S would be propagated both in the clockwise and counter-clockwise direction and received by the receiver R at the position of 12 o'clock.

2) If the source S is located at the 12 o'clock position and the receiver R is located at the 6 o'clock position, the first two signals would arrive at the receiving position R from the source, one of which is via the 3 o'clock direction and the other of which is via the 9 o'clock direction. The receiving signal would be the sum of the two identical signals, which have traveled with the same circumferential distance, if the pipe or pipeline is perfect without changing its electromagnetic properties. These two signals would be propagated around the circumference of the pipe or pipeline and received by the receiver R as these signals arrive at the receiver position.

3) If the source S is still located at the 12 o'clock position, as shown at 12 in FIG. 2B, and the receiver R shown at 14 in FIG. 2B is located either at the 3 o'clock position (as shown at 14 in FIG. 2B) or at the 9 o'clock position, then the signal via the 3 o'clock direction would arrive at the receiver 14 first, followed by the arrival of the signal via the 9 o'clock direction if the receiver R is located at the 3 o'clock position. The signal via the 9 o'clock direction would arrive first and the signal via the 3 o'clock direction would arrive second if the receiver R is located at 9 o'clock. Then the electromagnetic wave would be propagated again around the circumference of the pipe and the signals will be received by the receiver R as a function of time.

4) From the above illustration, the layout of the source S and the receiver R could be in a variety of ways such that the source S and receiver R would be located at any predesignated position around the circumference. Also within the broader scope of the present invention, the transmitter and receiver, instead of being at the same axial location, could be positioned at locations axially spaced a short distance from one another.

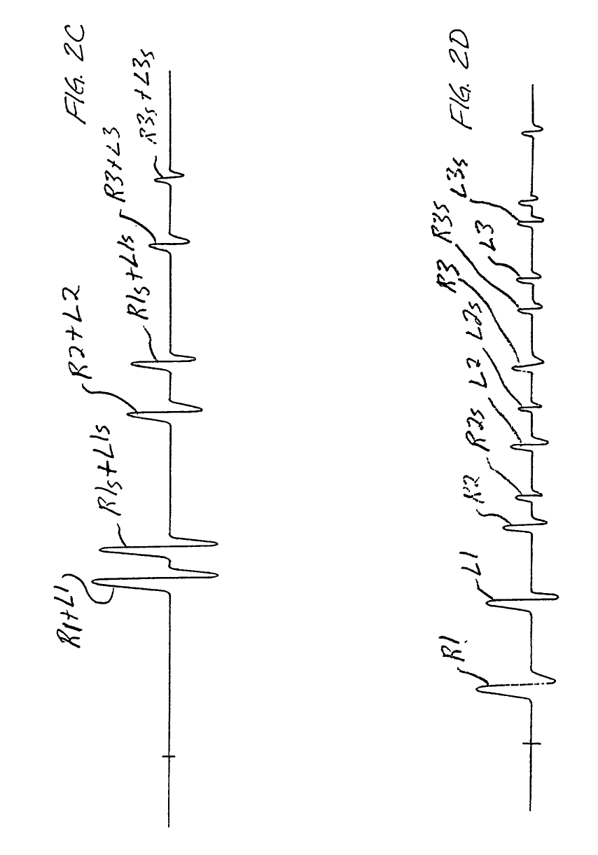

5) The application of the present invention to the detection of corrosion under insulation does not end right here. As a matter of fact, the measurement, for instance, could be continuously moving in the direction of interest. For example, suppose the source S and the receiver R are both located at the 12 o'clock position, then after each measurement the S and R could be moved to the next position along the axis of the pipe or pipeline. Moreover, the electromagnetic waves are propagated at the velocity slightly less than the velocity of light. At each location, the measurement could be repeated in a matter of a few nanoseconds, depending on the diameter of the pipe or pipeline. Therefore, the signal can be enhanced by repeated stacking, often 16, 32, 64 or more. Since the propagation of the electromagnetic waves are so fast, a man could continuously walk and take the data without stopping. The propagation of the electromagnetic waves traveling around the circumference at difference axial locations where the system is activated to take a reading are shown at 18 in FIG. 3.

6) It is equally important that testing be done in a manner that the source and receiver could be separated by a fixed distance, and move in unison, or the source could be fixed at the location with respect to the axial distance, and the receiver moves along the container axis away from the source at any locations axially and circumferentially. In this case, of course, the path of the electromagnetic wave propagation would be a helical path or paths such as what has already been described in a previously filed application, taking the minimum path according to the Format's principle. The text of that patent application is added to this provisional application to be made a part thereof, and intended to be part of the disclosure of this application.

7) In order to identify the individual arrivals of signals, it is necessary that the initial pulse width be made as short as possible. It was believed that the initial pulse width should be in the neighborhood of one nanosecond or less, which corresponds to a wavelength of about one foot or so. However, these pulse widths may be within a first preferred range of approximately one plus or minus on-half a nanosecond or a second preferred range of between approximately one-tenth of a nanosecond to approximately ten nanoseconds. An alternative type of initial pulse would be to use a one-sided step function. The exact parameters of the initial pulse width depend upon such factors as the characteristics of the container under test and the test equipment available.

Moreover, the process of deconvolution can be applied in the data analysis to pin down the exact arrival time and the spectrum analysis can be applied to examine the frequency contents of the signal to determine whether the signal has been propagated through the areas of corrosion. When a signal is propagated through the area of corrosion, some of the high frequency components could be damped out and made richer in lower frequencies. However, the change of frequency content for the signal, which is propagated through the area of corrosion or not, is very slight. Great care must be taken in order to discriminate the frequency content.

### DESCRIPTION OF THE PREFERRED EMBODIMENTS

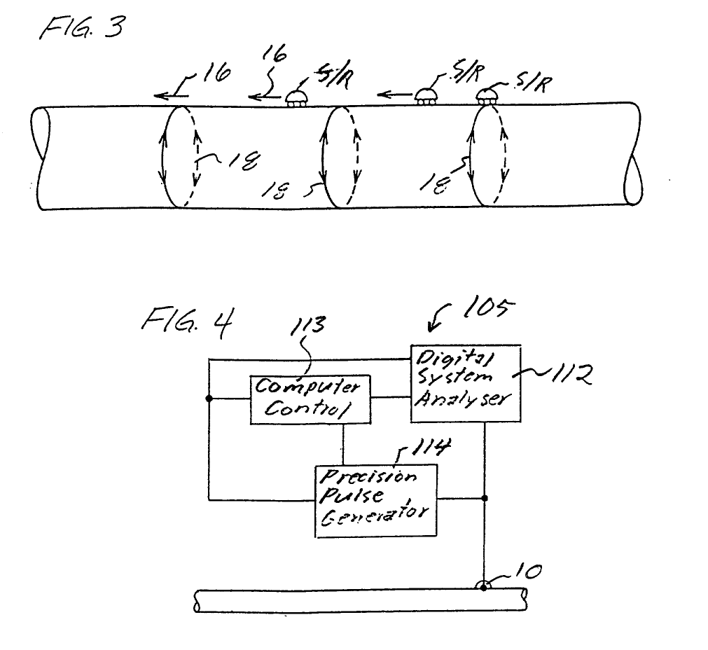

The above invention of the concept of detection of corrosion, defects, and other anomalies under insulation and shield can be implemented by the apparatus and instruments as shown in FIG. 4.

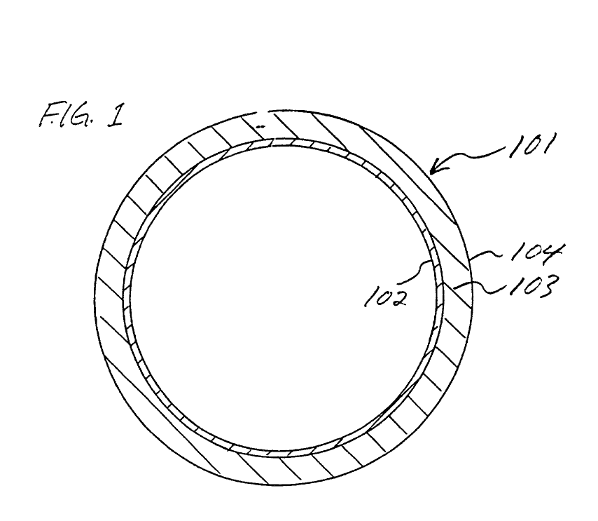

To describe the present invention further, with reference to FIG. 1, there is shown a pipe section 101 which is under scrutiny. In this instance, this pipe 101 is or may be a large-diameter pipe or pipeline that would typically be used in the main trunk or the trans-continental pipeline. The pipe itself 102 is made of steel and surrounded by a coat and/or a layer of insulation and a shield layer 104 of metallic (galvanized steel and/or aluminum) material, plastic material, tar, and/or asphalt.

The apparatus or system to implement the present invention is designated 105, and it comprises a self contained dual source and receiver 10 (or separate transmitter and receiver), a control unit for data acquisition and analysis, which comprises a digital signal analyzer 112 and computer control 113, and a precision pulse generator 114. The pulse generator unit 114 triggers the source S and the receiver R (designated S/R). The source S in turn send s a finite duration predesignated pulse, typically in the neighborhood of one nanosecond. This system 105 is an integrated portable unit for the field operation.

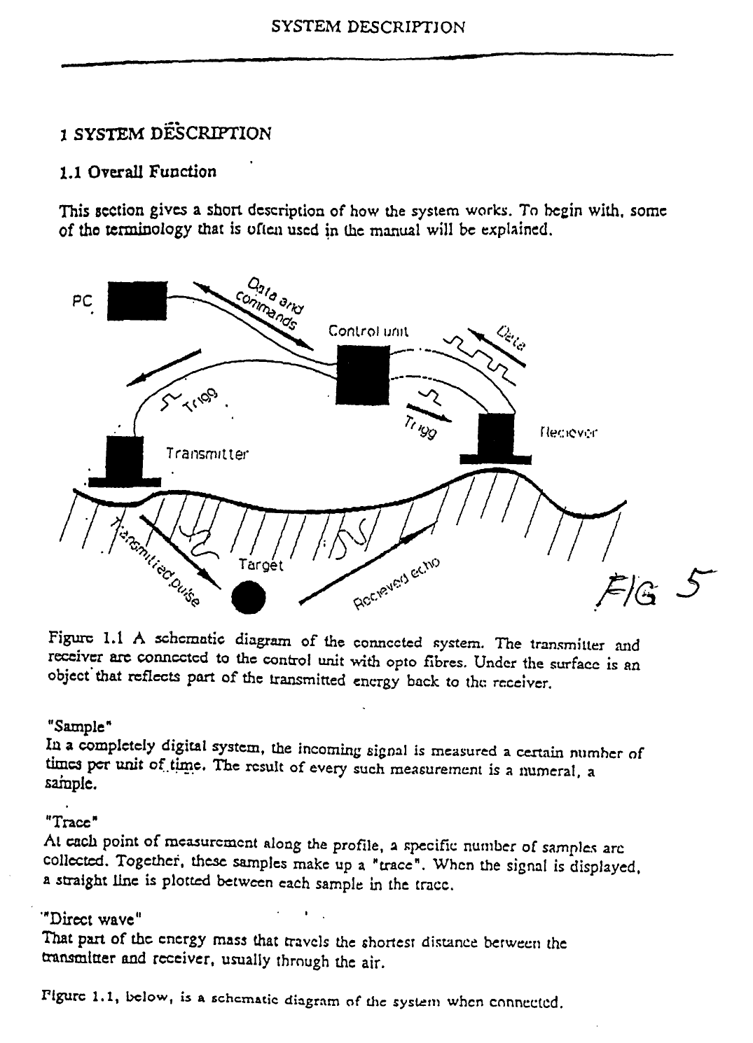

One of the other instruments which came to the attention of the applicant is that of Ground Penetrating-Radar (GPR) (see FIG. 5), which traditionally has been used in the archaeological or environmental applications and can be adapted to the present invention. This is shown in FIG. 5. To the best knowledge of the applicant, no one has thought of using the instrument for inspection of corrosion under installation. There are several sources of such GPR equipment available in the commercial market, namely from GSSI, RAMAC and others.

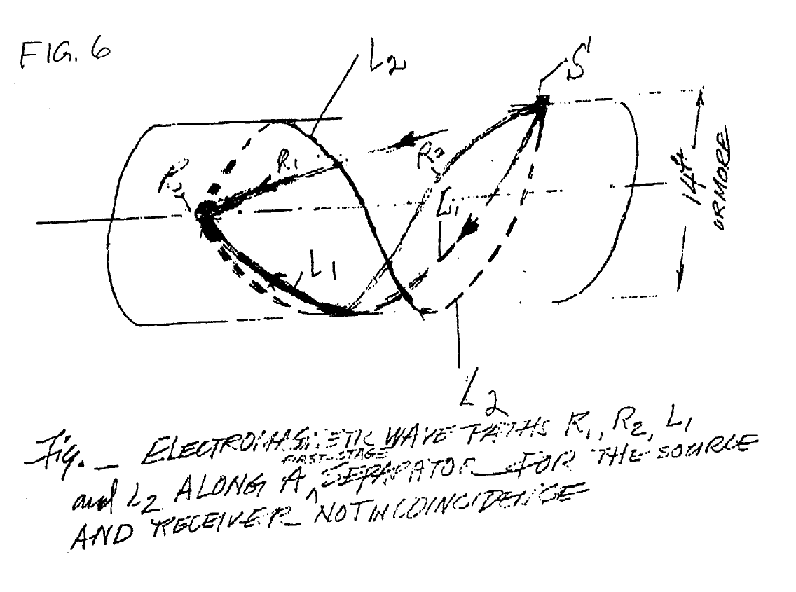

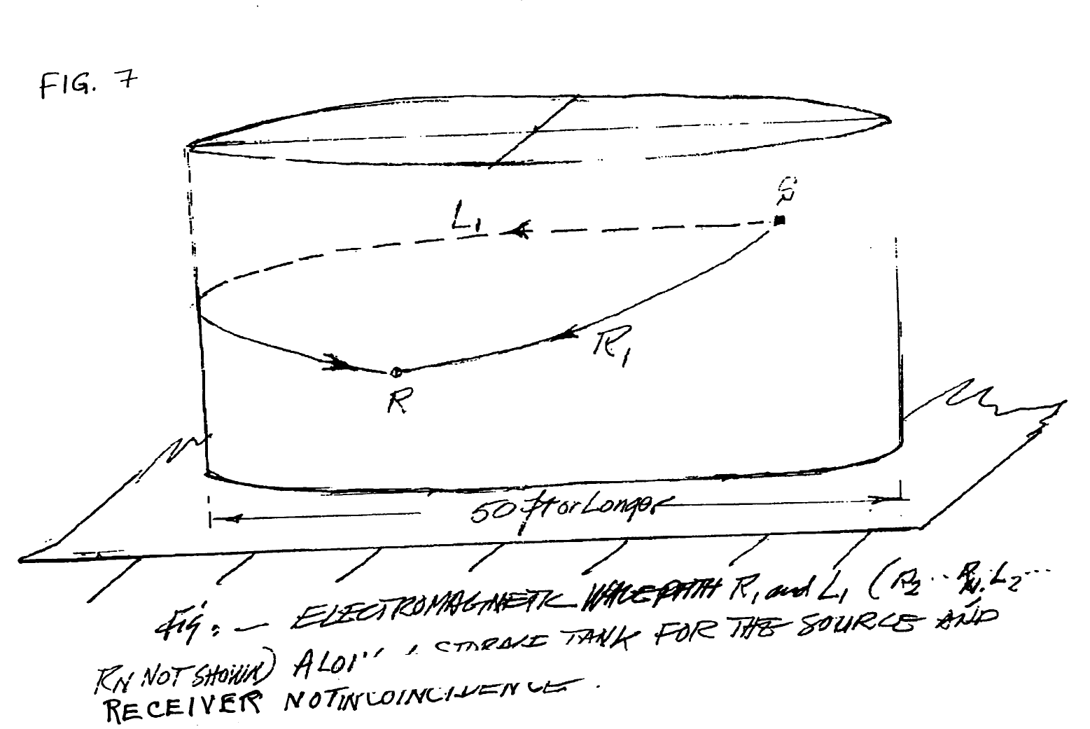

As generally described above, the present invention has application to the testing of a number of different container types and sizes. In addition to the cylindrical pipe discussed herein with reference to FIGS. 1-4, the containment vessel of a first stage separator such as that depicted in FIG. 6 or a storage tank such as that depicted in FIG. 7 can be tested using the principles of the present invention. The exemplary separator vessel shown in FIG. 6 is cylindrical and has a diameter of fourteen feet, while the exemplary storage tank shown in FIG. 7 is generally cylindrical and has a diameter of fifty feet or more.

Referring again to FIGS. 2-4, for a description of one preferred embodiment, we take a typical segment of a 60 inch pipeline.

Reference is made to FIGS. 2A and 2B for the cases of the S/R are in coincidence at the 12 o'clock position, and the S located at the 12 o'clock position and the R located at the 3 o'clock position, respectively.

1. Case of the S/R in Coincidence at the 12 o'Clock Position.

As described in FIG. 2A, the two signals emitted by the source S, one of which is propagated in the clockwise direction will be received by the receiver R at the 12 o'clock position. Moreover, this first signal is designated as R1, the second signal is designated as R2; the third as R3, the fourth as R4, and so on. Likewise, the first signal propagated around the circumference of the pipe in the counter-clockwise direction and received by the receiver R at the 12 o'clock position is designated as L1, and the subsequent arrivals around the circumference and received by the receiver R at the 12 o'clock position are designated by L2, L3, . . . , respectively. These two signals would continue to propagate around the circumference of the pipe or pipeline. Each time the two signals reach the 12 o'clock position and will be received by the receiver R.

Assuming the phase velocity for the steel pipe or pipeline is 0.95 ft/ns, and that of the shield is 0.92 ft/ns. FIG. 2C gives the expected time series. The symbols of L1s, L2s . . . , and R1s, R2s, . . . , correspond to the electromagnetic waves propagated clockwise and counter-clockwise around the shield.

2. Case of the S Located at 12 o'Clock Position and the R Located at the 3 o'Clock Position.

FIG. 2B describes the case for the source and the receiver which are located at the 12 o'clock and 3 o'clock position, respectively. The designation of the arrival signals at the receiver R at the 3 o'clock position is the same as in the case of the source and receiver coincidence, namely the signals propagated in the clockwise direction around the circumference of the pipe or pipeline are R1, R2, . . . , and those propagated in the counter-clockwise direction are L1, L2, . . . , except the signal of R1 is propagated only one quarter of the circumference and the L1 is propagated three quarters of the circumference of the pipe or pipeline. Since the insulating materials function as an insulator, the electromagnetic waves transmitted from the pipe through the insulation to the shield is virtually perpendicular to the pipe or pipeline.

FIG. 2D gives the expected time series with the above given phase velocities for the shield and pipe for the present case, which may be compared with that for the case of the R/S in coincidence. For the present case, the signals are much more complicated. The designations of R1s, R2s, . . . and L1s, L2s, . . . are the electromagnetic waves which are propagated around the shield.

The same basic principles are applied to detection of anomalies in the separator depicted in FIG. 6 and storage tank depicted in FIG. 7. As shown in FIG. 6, signals R1, R2, and so on propagate in the right hand direction from the source S to the receiver R, while signals L1, L2, and so on propagate in the right hand direction from the source S to the receiver R. Similarly, FIG. 7 shows that signals R1 and so on propagate in the right hand direction from the source S to the receiver R, while signals L1 and so on propagate in the left hand direction from the source S to the receiver R.

Whether the invention is applied to a pipe or pipeline as described with reference to FIGS. 2A-D, a separator as described with reference to FIG. 6, or a storage tank as described with reference to FIG. 7, the detection of electromagnetic anomalies related to corrosion and/or defects such as typical corrosion will be described below.

3. Detection of Corrosion

Suppose there is a single corrosion which is centered at the 6 o'clock position, extending from 5:30 to 6:30 o'clock position. The electromagnetic properties at the location of the corrosion are different from the rest of the cross section of the pipe or pipeline. As the signal is propagated through the corrosion section, it experiences electromagnetic property changes; normally these electromagnetic property changes would retard the phase velocity and result in a higher attenuation rate. For the case of the S/R in coincidence, the travel time for the signal R1 and L1 would be exactly the same; moreover, the second arrivals L2 and R2 are also the same. Nevertheless, the travel times for L1 and R1 are different in comparison with exactly the same configuration if the corroded section centered at the 6 o'clock were not there. Not only would the travel time be different between these two cases but also the wave forms would also be different. Further, the attenuation for the case of the presence of the corrosion would be higher than that for the case free from the corrosion section. Naturally, the precision of the measurements are crucial in the discrimination in detecting the corrosion under insulation and shield.

Now for the case of the source S located at the 12 o'clock position and the receiver R located at the 3 o'clock position, assuming the corrosion section is located exactly at the same location as in the previous case. The first arrival of R1 would not be contaminated by the corrosion section, and the arrival time would be normal; whereas the first arrival of L1 would be traveled through the corrosion section to give a delay the amount of which is depending on the severity of the corrosion. The subsequent arrivals all would be the electromagnetic waves propagated through the corrosion section to cause time delay in comparison with that if there were no corrosion.

It is obvious that various modifications could be made to the present invention without departing from the basic teachings thereof.

What is claimed:

1. A method of determining whether anomalies exist on the surface of an electrically conductive container, comprising the steps of:
introducing an electromagnetic pulse into the container at a first test location on the container to generate a plurality of electromagnetic signals that propagate from the first location to a second test location on the container, where each of the plurality of electromagnetic signals propagates along a unique propagation path between the first and second test locations;
detecting the plurality of the electromagnetic signals at the second test location; and
determining the existence of surface anomalies between the first and second testing locations by comparing at least one given characteristic of at least one of the detected electromagnetic signals with the given characteristic of at least another of the detected electromagnetic signals.

2. A method as recited in claim 1, in which the first and second testing locations are located at the same physical location on the container.

3. A method as recited in claim 1, in which the first and second testing locations are spaced from each other along an axis of the container.

4. A method as recited in claim 1, in which the first and second testing locations are spaced from each other about the circumference of the container.

5. A method as recited in claim 1, in which:
the container is generally cylindrical;
at least one of the propagation paths has both an axial component and a lateral component in a first direction about the circumference of the container; and
at least one of the propagation paths has both an axial component and a lateral component in a second direction about the circumference of the container, where the second direction is opposite to the first direction.

6. A method as recited in claim 1, in which at least one of the propagation paths is helical.

7. A method as recited in claim 1, in which the container is generally cylindrical.

8. A method as recited in claim 7, in which the container is selected from the group of containers consisting of elongate objects such as pipes and pipelines and three-dimensional vessels such as separator containers and storage tanks.

9. A method as recited in claim 1, in which the given characteristic is one of the characteristics in the group of electromagnetic characteristics consisting of travel time, propagation speed, signal attenuation, phase velocity, waveform, and signal spectrum.

10. A method as recited in claim 1, in which the surface anomaly to be detected is at least one anomaly selected from the group of anomalies consisting of corrosion and defects.

11. A method of detecting corrosion in a generally cylindrical, conductive container to be tested such as a pipe, pipeline, separator container, and storage tank, the method comprising the steps of:
arranging a signal source at a first test location on the container to be tested;
arranging a signal receiver at a second test location on the container to be tested;
operating the signal source to generate a plurality of electromagnetic signals in the container to be tested, where each electromagnetic signal follows a unique propagation path from the first test location to the second test location and the corrosion lies in some but not all of the propagation paths;
operating the signal receiver to detect at least first and second electromagnetic signals of the plurality of electromagnetic signals that have propagated from the first test location to the second test location, where the first electromagnetic signal propagated through the corrosion and the second propagation signal did not propagate through the corrosion; and
comparing at least one electromagnetic characteristic of the first and second electromagnetic signals to determine the existence of the corrosion.

12. A method as recited in claim 11, in which the first and second testing locations are located at the same physical location on the container.

13. A method as recited in claim 11, in which the first and second testing locations are spaced from each other along an axis of the container.

14. A method as recited in claim 11, in which the first and second testing locations are spaced from each other about the circumference of the container.

15. A method as recited in claim 11, in which:
the propagation path of the first electromagnetic signal has both an axial component and a lateral component in a first direction about the circumference of the container; and
the propagation path of the second electromagnetic signal has both an axial component and a lateral component in a second direction about the circumference of the container, where the second direction is opposite to the first direction.

16. A method as recited in claim 11, in which the propagation paths of the first and second electromagnetic signals are helical.

17. A method as recited in claim 11, in which the given characteristic is one of the characteristics in the group of electromagnetic characteristics consisting of travel time, propagation speed, signal attenuation, phase velocity, waveform, and signal spectrum.

18. A method as recited in claim 1, in which the container is at least partially encased in a material selected from the group of materials consisting of insulation and shielding.

19. A method as recited in claim 11, in which the container is at least partially encased in a material selected from the group of materials consisting of insulation and shielding.

20. A method as recited in claim 1, in which the first and second testing locations are spaced at any locations axially or circumferentially.

21. A method as recited in claim 11, in which the first and second testing locations are spaced at any locations axially or circumferentially.

22. A method as recited in claim 1, further comprising the step of:
introducing an electromagnetic pulse into the container at the second test location on the container to generate a plurality of electromagnetic signals that propagate from the second test location to the first test location on the container, where each of the plurality of electromagnetic signals propagates along a unique propagation path between the second and first test locations; and
detecting the plurality of the electromagnetic signals at the first test location.

23. A method as recited in claim 11, further comprising the step of:
introducing an electromagnetic pulse into the container at the second test location on the container to generate a plurality of electromagnetic signals that propagate from the second test location to the first test location on the container, where each of the plurality of electromagnetic signals propagates along a unique propagation path between the second and first test locations; and
detecting the plurality of the electromagnetic signals at the first test location.
